(19) United States
(12) Patent Application Publication
(10) Pub. No.: US 2014/0311675 A1
(43) Pub. Date: Oct. 23, 2014

(54) SINGLE WAFER ETCHING APPARATUS

(71) Applicant: LG SILTRON INC., Gyeongsangbuk-do (KR)

(72) Inventors: Jaehwan Yi, Gyeongsangbuk-do (KR); Eunsuck Choi, Gyeongsangbuk-do (KR)

(73) Assignee: LG SILTRON INC., Gyeongsangbuk-do (KR)

(21) Appl. No.: 14/357,203

(22) PCT Filed: Dec. 6, 2012
(86) PCT No.: PCT/KR2012/010573

§ 371 Date: May 8, 2014

(30) Foreign Application Priority Data
Dec. 16, 2011 (KR) 10-2011-0136690

(51) Int. Cl. H01L 21/67

(52) U.S. Cl. CPC H01L 21/6708
USPC 156/345.33

(57) ABSTRACT

Provided is a single wafer etching apparatus etching wafers one at a time. According to the present invention, the single wafer etching apparatus may not only discharge gas by vibrating the wafer even in the case that gas, a byproduct of an etching reaction, is generated, but may also prevent the gas from adsorbing on a surface of the wafer. Also, since the single wafer etching apparatus may directly heat each region of the wafer, the single wafer etching apparatus may uniformly maintain a reaction temperature by heating to higher temperatures from a circumferential direction toward the center of the wafer, even in the case that the temperature of an etching solution increases from the center of the wafer toward the circumferential direction due to the fact that etching is performed while the etching solution moves from the center of the wafer toward the circumferential direction. Therefore, the single wafer etching apparatus may not only uniformly maintain a degree of etching regardless of a position on the wafer, but may also increase flatness.

### CROSS-REFERENCE TO RELATED APPLICATIONS

The present application is a national phase application of PCT application PCT/KR2012/010573 filed Dec. 6, 2012, which claims the priority benefit of Korean patent application 10-2011-0136690 filed Dec. 16, 2011, the disclosures of which are incorporated herein by reference.

### BACKGROUND OF THE INVENTION

1. Field of the Invention

The present disclosure relates to a single wafer etching apparatus in which a wafer rotating by a rotary plate is etched one at a time by an etching solution sprayed through a nozzle.

2. Description of the Related Art

Organizations In general, a wafer etching process is performed to remove damages occurred during mechanical processing of a wafer.

Recently, the trend for increasing the diameter of a wafer as well as increasing integration density and pattern fineness of a semiconductor device has emerged in the semiconductor industry. A size of a batch-type etching apparatus may not only increase to etch a large-diameter wafer, but consumption of an etching solution may also increase. Therefore, a single wafer etching apparatus processing one wafer at a time has been widely used in order to effectively etch a large-diameter wafer.

Typical single wafer etching apparatuses are disclosed in Korean Patent Application Nos. 2008-0019366, 2008-7019037, and 2009-0002214, in which a wafer is fixed on a rotary plate by vacuum suction and an etching solution is allowed to be provided to a front surface or a back surface of the wafer from an etching nozzle as the rotary plate rotates. At this time, the etching nozzle moves by a movement mechanism and the etching solution dropped on a surface of the wafer spreads on the entire surface of the wafer due to a centrifugal force as the rotary plate rotates.

Thus, with respect to the typical single wafer etching apparatuses, since the etching solution covers the entire wafer, etching is performed on the entire surface of the wafer. Therefore, a large amount of gas, a byproduct from an etching reaction, may not only be adsorbed on the surface of the wafer, but the gas may also prevent the surface of the wafer from reacting with a newly provided etching solution, and thus, flatness of the wafer may deteriorate.

Meanwhile, a degree of etching caused by the etching reaction may be rapidly affected by temperature. However, with respect to the typical single wafer etching apparatuses, an etching solution provided at the center of a wafer moves toward a circumferential direction of the wafer due to a centrifugal force and etching may be more severe toward the circumferential direction of the wafer according to an increase in the temperature of the etching solution as the reaction between the etching solution and the surface of the wafer is repeated, and thus, flatness of the wafer may deteriorate.

### SUMMARY OF THE PRESENTLY CLAIMED INVENTION

Embodiments provide a single wafer etching apparatus able to remove gas, a byproduct between an etching solution and a surface of a wafer.

Embodiments also provide a single wafer etching apparatus able to uniformly maintain the temperature of a reaction between the etching solution and the surface of the wafer regardless of a position on the surface of the wafer.

### Solution to Problem

In one embodiment, a single wafer etching apparatus includes: a rotary plate having a wafer stably placed thereon and having a diameter smaller than that of the wafer; a spray nozzle spraying an etching solution on the wafer stably placed on the rotary plate; a driver rotating the rotary plate; and a vibrating device vibrating the rotary plate during the etching solution is sprayed from the spray nozzle.

The single wafer etching apparatus may further include a heating device heating each region of the rotary plate during the etching solution is sprayed from the spray nozzle.

The heating device may include a heat supplying substrate having divided regions on the rotary plate, a plurality of power cables transferring power to the each region of the heat supplying substrate, and a power supplying unit supplying power to the power cables.

The heat supplying substrate may include a plurality of heat supplying regions divided from a center of the rotary plate in a circumferential direction and operating at lower temperatures from the center of the rotary plate toward the circumferential direction.

The vibrating device may be an oscillator included in the driver.

The vibrating device may be a quartz vibrator included between the rotary plate and the wafer, or the vibrating device may be a quartz vibrator, the rotary plate having the wafer mounted thereon.

In another embodiment, a single wafer etching apparatus includes: a rotary plate having a wafer stably placed thereon; a spray nozzle spraying an etching solution on the wafer stably placed on the rotary plate; a driver rotating the rotary plate; a heat supplying substrate included on the rotary plate and heating each region of the rotary plate; and an oscillator included in the driver and oscillating the rotary plate.

The heat supplying substrate may include a plurality of heat supplying regions divided from a center of the rotary plate in a circumferential direction and operating at lower temperatures from the center of the rotary plate toward the circumferential direction.

The oscillator may be linked with the spray nozzle and the heat supplying substrate.

In further another embodiment, a single wafer etching apparatus includes: a rotary plate having a wafer stably placed thereon and having a diameter smaller than that of the wafer; a spray nozzle spraying an etching solution on the wafer stably placed on the rotary plate; a driver rotating the rotary plate; a heat supplying substrate included on the rotary plate and heating each region of the rotary plate; and a vibrator included in the heat supplying substrate and vibrating the rotary plate.

The heat supplying substrate may include a plurality of heat supplying regions divided from a center of the rotary plate in a circumferential direction and operating at lower temperatures from the center of the rotary plate toward the circumferential direction.

The vibrator may be linked with the spray nozzle and the heat supplying substrate.

### Advantageous Effects of Invention

Since a single wafer etching apparatus according to the present invention includes a vibrating device vibrating a rotary plate having a wafer mounted thereon, the single wafer etching apparatus may not only discharge gas by vibrating the wafer even in the case that gas, a byproduct of an etching reaction, is generated, but may also prevent the gas from adsorbing on the surface of the wafer and may increase flatness by allowing the reaction with the surface of the wafer to be smoothly performed even in the case that the etching solution is continuously supplied.

Also, since the single wafer etching apparatus according to the present invention includes a heating device heating each region of the rotary plate having the wafer mounted thereon, the single wafer etching apparatus may uniformly maintain a reaction temperature by heating to higher temperatures from a circumferential direction toward the center of the wafer even in the case that the temperature of the etching solution increases from the center of the wafer toward the circumferential direction due to the fact that etching is performed while the etching solution moves from the center of the wafer toward the circumferential direction. The single wafer etching apparatus according to the present invention may not only uniformly maintain a degree of etching regardless of a position on the wafer, but may also increase flatness.

### BRIEF DESCRIPTION OF THE DRAWINGS

FIGS. 1 and 2 illustrate a first embodiment of a single wafer etching apparatus according to the present invention;

FIG. 3 illustrates an example of a heating device of the single wafer etching apparatus according to the present invention;

FIG. 4 illustrates a gas discharging phenomenon during a process of operating the first embodiment of the single wafer etching apparatus according to the present invention;

FIG. 5 illustrates a second embodiment of the single wafer etching apparatus according to the present invention; and

FIG. 6 illustrates a third embodiment of the single wafer etching apparatus according to the present invention.

### DETAILED DESCRIPTION

Hereinafter, the embodiment will be described in detail with reference to the accompanying drawings. The invention may, however, be embodied in many different forms and should not be construed as being limited to the embodiments set forth herein; rather, that alternate embodiments included in other retrogressive inventions or falling within the spirit and scope of the present disclosure can easily be derived through adding, altering, and changing.

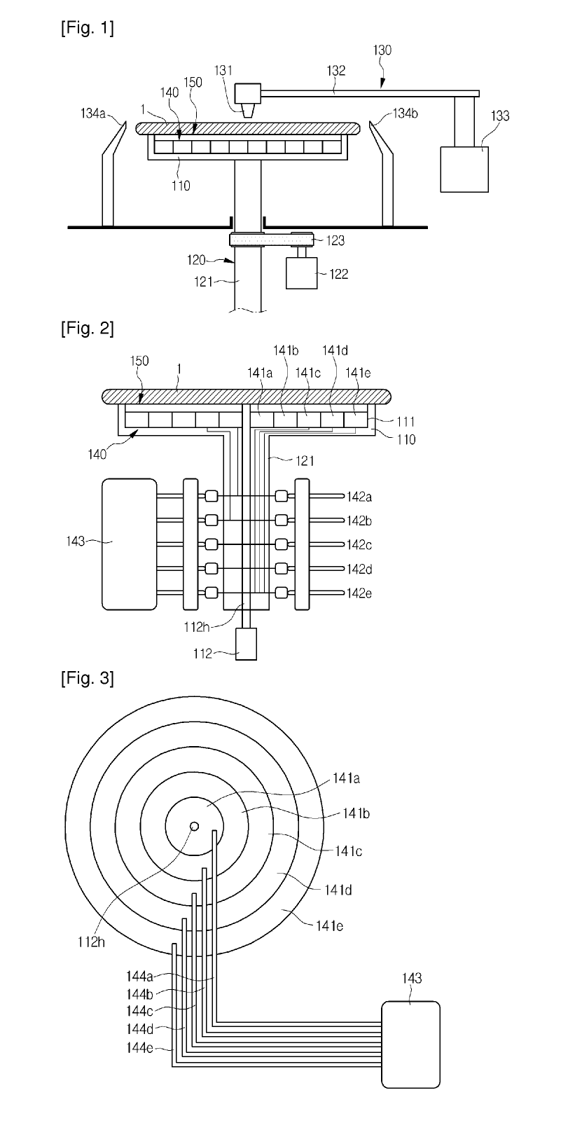

FIGS. 1 and 2 illustrate a first embodiment of a single wafer etching apparatus according to the present invention, and FIG. 3 illustrates an example of a heating device of the single wafer etching apparatus according to the present invention.

As shown in FIGS. 1 and 2, an example of the single wafer etching apparatus according to the present invention may include a rotary plate 110 having a wafer 1 mounted thereon, a driver 120 rotating the rotary plate 110, a spraying device 130 spraying an etching solution on a surface of the wafer 1 mounted on the rotary plate 110, a heating device 140 heating the rotary plate 110, and a vibrator 150 vibrating the rotary plate 110.

The rotary plate 110 has the shape of a circular plate, in which a diameter of the rotary plate 110 is smaller than that of the wafer so as to allow the etching solution dropped on the wafer to be easily scattered in addition to facilitate vacuum suction of the wafer. Also, the rotary plate 110 includes a rest portion 111 at the center of an upper surface thereof, in which the vibrator 150 may be mounted. At this time, the rotary plate 110 is connected to a vacuum supplying unit 112 generating a vacuum force so as to fix the wafer 1 by vacuum, and a vacuum path 112h connecting between the vacuum supplying unit 112 and the center of the wafer is included. The wafer 1 may be mounted on the rotary plate 110 or may be stably placed in the rest portion 111 of the rotary plate 110.

The driver 120 includes a rotation axis 121 connected to the center of a lower surface of the rotary plate 110, a motor 122 providing power to the rotation axis 121, and a pulley and a belt 123 transferring power between the rotation axis 121 and the motor 122. At this time, the motor 122 and the rotation axis 121 may be directly connected to each other. However, since a heating device 140 to be described below in addition to the vacuum path 112h and the vacuum supplying unit 112 are included through the rotation axis 121, the motor 122 and the rotation axis 121 may be connected in such a manner that power is transferred through the separate pulley and belt 123.

The spraying device 130 may include a spray nozzle 131, a movement mechanism 132, an etching solution supplying unit 133, and guides 134a and 134b.

In particular, the spray nozzle 131 is disposed to have a predetermined spacing from an upper side of the center of the rotary plate 110 and configured to be able to spray the etching solution on the center of the surface of the wafer 1. At this time, the spray nozzle 131 may be controlled by including a separate controller adjusting a spray angle, or adjusting a height from the wafer 1, or controlling spraying or not spraying of the etching solution. The spray nozzle 131 may be configured to be able to spray a rinse solution in addition to the etching solution and similarly, may be configured to adjust the spray angle, the height from the wafer, and spraying or not spraying of the rinse solution.

Also, the movement mechanism 132 may be connected to spray the etching solution stored in the etching solution supplying unit 133 to the spray nozzle 131, may control the spray nozzle 131 to be movable on the surface of the wafer 1, and may be controlled by including a separate controller.

Also, the etching solution supplying unit 133 may be included so as to be spaced apart from the rotary plate 110 and configured to allow other etching solutions to be stored therein according to the type of the wafer 1.

Also, the plurality of guides 134a and 134b are included around the rotary plate 110 and may prevent scattering of the etching solution sprayed on the surface of the wafer 1 to the surroundings thereof due to a centrifugal force as the wafer 1 on the rotary plate 110 rotates.

The heating device 140 heats the wafer 1 by using a conduction method having high heat transfer efficiency, may heat each region of the wafer 1 to a different temperature, and may include heat supplying substrates 141a, 141b, 141c, 141d, and 141e, power cables 142a, 142b, 142c, 142d, and 142e, and a power supplying unit 143.

The heat supplying substrates 141a, 141b, 141c, 141d, and 141e may be formed of heat supplying regions in the shape of multiple ring plates having divided regions in a circumferential direction. At this time, the heat supplying substrates 141a, 141b, 141c, 141d, and 141e may be formed of materials having different resistances so as to heat the wafer to higher temperatures from the circumferential direction toward the center, even in the case that the same power is applied thereto. The heat supplying substrates 141a, 141b, 141c, 141d, and 141e may be respectively connected to the power cables 142a, 142b, 142c, 142d, and 142e for each region and may receive power from the power supplying unit 143. Meanwhile, in the case that the heat supplying substrates 141a, 141b, 141c, 141d, and 141e are formed of a material having the same resistance, power supplied from the power supplying unit 143 to the power cables 142a, 142b, 142c, 142d, and 142e, that is, power supplied to each region of the heat supplying substrates 141a, 141b, 141c, 141d, and 141e may be controlled so as to control a temperature for the each region of the heat supplying substrates 141a, 141b, 141c, 141d, and 141e.

The vibrator 150 has the shape of a circular plate and is stably placed on the rotary plate 110 so as to be included between the wafer 1 and the heat supplying substrates 141a, 141b, 141c, 141d, and 141e, and a separate power supplying unit (not shown) able to apply power may be connected thereto. At this time, the vibrator 150 acts to vibrate the wafer 1 in order to discharge gas generated due to the reaction between the etching solution and the surface of the wafer 1 during an etching process. Therefore, the vibrator 150 may be operated to generate vibration during the etching process and may be controlled to vibrate during the etching solution is sprayed from the spray nozzle 131 or the heating device 140 is operated.

The vibrator 150 may be formed of various materials, such as quartz and sapphire, and a quartz vibrator may be used. The quartz vibrator 150 is formed by connecting conductor electrodes on both sides of a thin piece prepared by cutting quartz in a specific direction with respect to the crystal axis thereof and is operated to vibrate by the addition of a deformation force due to an electrostrictive effect according to the application of a voltage. Although changes in temperature may occur due to the reaction between the etching solution and the surface of the wafer 1 in an etching process environment, the quartz vibrator 150 may be used in the etching process environment because it is stable with respect to the changes in temperature.

Meanwhile, a process of operating an example of the single wafer etching apparatus configured as above is described below.

First, when the vacuum supplying unit 112 operates, a vacuum state is maintained through the vacuum path 112h and the wafer 1 being in contact with the vacuum path 112h is adsorbed to the vibrator 150.

Thereafter, when the motor 122 operates, the rotation axis 121 and the rotary plate 110 rotate as power is transferred by the belt 123, and thus, the wafer 1 rotates. Also, when the etching solution supplying unit 133 operates, an etching process is performed while an etching solution is sprayed on the surface of the wafer 1 through the spray nozzle 131. At this time, etching is performed while the etching solution is reacted with the surface of the wafer 1, an etching reaction occurs while the etching solution also moves from the center toward a circumferential direction as the wafer 1 rotates, and the temperature of the etching solution increases as the etching reaction further proceeds.

In the case that the power supplying unit 143 operates during the etching process, each region of the heat supplying substrates 141a, 141b, 141c, 141d, and 141e may be heated to a different temperature, and may be heated to a higher temperature from the circumferential direction toward the center. Therefore, the etching solution may maintain higher temperature from the center toward the circumferential direction. However, since the heat supplying substrates 141a, 141b, 141c, 141d, and 141e may maintain higher temperature from the circumference toward the center, the etching reaction of the entire wafer 1 may occur at a uniform temperature due to the etching solution and the heat supplying substrates 141a, 141b, 141c, 141d, and 141e, and thus, a uniform flatness may be maintained over the entire wafer 1.

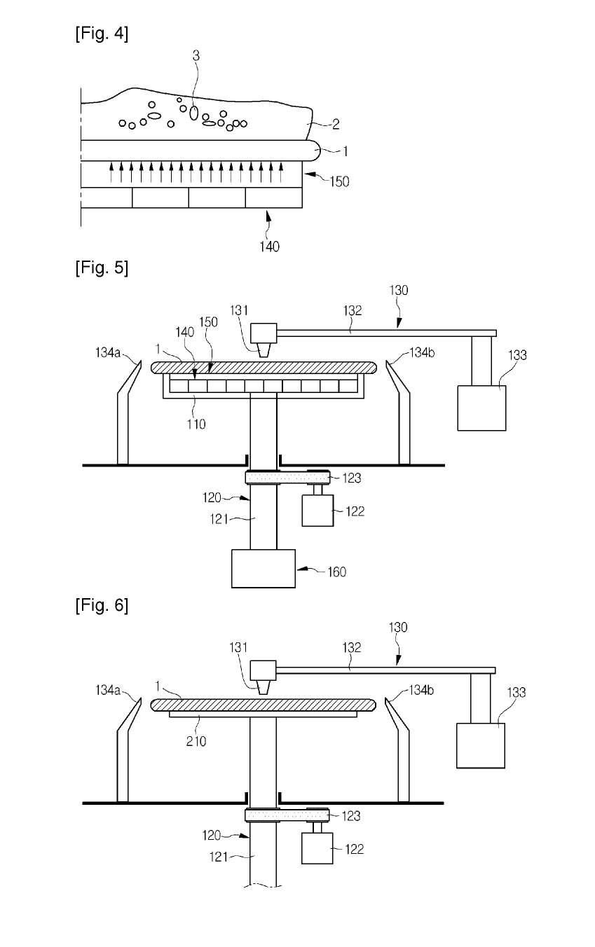

FIG. 4 illustrates a gas discharging phenomenon during a process of operating the first embodiment of the single wafer etching apparatus according to the present invention.

During the etching process is performed as above, gas may be generated as a byproduct of the etching reaction to remain in the etching solution or may be adhered to the surface of the wafer 1 as shown in FIG. 4. At this time, when the vibrator 150 operates, gas 3 generated from the etching reaction may escape from an etching solution 2 as the gas moves due to vibration or may be detached from the surface of the wafer 1. Therefore, since the gas remaining on the wafer 1 may be removed, the newly provided etching solution 2 may react with the surface of the wafer 1, and thus, flatness may be increased.

Meanwhile, in the example of the single wafer etching apparatus, the rotary plate 110 may be included in order to install the heating device 140 in the case that the heating device 140 is included as shown in FIG. 1. However, the heating device 140 may be omitted. In the case in which the heating device 140 is omitted, the rotary plate 110 may not be included, and as shown in FIG. 6, the wafer 1 may not only be mounted on a vibrator 210 itself, but the vibrator 210 may be configured to substitute for the rotary plate for vacuum suction during the rotation.

FIG. 5 illustrates a second embodiment of the single wafer etching apparatus according to the present invention.

As shown in FIG. 5, the second embodiment of the single wafer etching apparatus according to the present invention may be configured to include a rotary plate 110 having a wafer stably placed thereon, a driver 120 rotating the rotary plate 110, a spraying device 130 spraying an etching solution on a surface of the wafer 1 mounted on the rotary plate 110, a heating device 140 directly heating each region of the wafer 1 mounted on the rotary plate 110, and an oscillator 160 oscillating the driver 120. At this time, since the rotary plate 110, the driver 120, the spraying device 130, and the heating device 140 are configured in the same manner as those of the first embodiment of the single wafer etching apparatus, detailed descriptions thereof will be omitted.

The oscillator 160 may be connected to a lower portion of a rotation axis 121 so as to directly oscillate the rotation axis 121. The oscillator 160 may be connected to a motor 122 or a belt 123 providing power to the rotation axis 121 so as to indirectly oscillate the rotation axis 121. At this time, the oscillator 160 is a device transforming a rotational force into a motion in a vertical direction, and since the oscillator 160 may be variously configured, the configuration thereof is not limited.

In particular, in the case that a rotational center of the rotation axis 121 vibrates in an inclined state or in a changed state, spray angle and spray height may be affected when the etching solution is sprayed on the surface of the wafer 1, and thus, quality of the wafer 1 may not be assured. Therefore, in order to assure the etching quality of the wafer 1, the oscillator 160 may vibrate only in the vertical direction while maintaining the center of the rotation axis 121 in a vertical state. At this time, the oscillator 160 is also controlled to oscillate during the etching process and may be operated so as to be linked with the spray nozzle 131 or the heating device 140.

Since the second embodiment of the single wafer etching apparatus configured as above is operated in the same manner as that of the first embodiment, detailed descriptions thereof will be omitted.

### INDUSTRIAL APPLICABILITY

Since wafers may be etched one at a time by using an etching solution, the present embodiment may be industrially applied.

What is claimed is:

1. A single wafer etching apparatus comprising:
a rotary plate having a wafer stably placed thereon and having a diameter smaller than that of the wafer;
a spray nozzle spraying an etching solution on the wafer stably placed on the rotary plate; a driver rotating the rotary plate; and
a vibrating device vibrating the rotary plate during the etching solution is sprayed from the spray nozzle.

2. The single wafer etching apparatus according to claim 1, further comprising a heating device heating each region of the rotary plate during the etching solution is sprayed from the spray nozzle.

3. The single wafer etching apparatus according to claim 2, wherein the heating device comprises: a heat supplying substrate having divided regions on the rotary plate; a plurality of power cables transferring power to the each region of the heat supplying substrate; and a power supplying unit supplying power to the power cables.

4. The single wafer etching apparatus according to claim 3, wherein the heat supplying substrate comprises a plurality of heat supplying regions divided from a center of the rotary plate in a circumferential direction and operating at lower temperatures from the center of the rotary plate toward the circumferential direction.

5. The single wafer etching apparatus according to any one of claims 1 to 4, wherein the vibrating device is an oscillator included in the driver.

6. The single wafer etching apparatus according to any one of claims 1 to 4, wherein the vibrating device is a quartz vibrator included between the rotary plate and the wafer.

7. The single wafer etching apparatus according to any one of claims 1 to 4, wherein the vibrating device is a quartz vibrator, the rotary plate having the wafer mounted thereon.

8. A single wafer etching apparatus comprising:
a rotary plate having a wafer stably placed thereon;
a spray nozzle spraying an etching solution on the wafer stably placed on the rotary plate;
a driver rotating the rotary plate;
a heat supplying substrate included on the rotary plate and heating each region of the rotary plate; and
an oscillator included in the driver and oscillating the rotary plate.

9. The single wafer etching apparatus according to claim 8, wherein the heat supplying substrate comprises a plurality of heat supplying regions divided from a center of the rotary plate in a circumferential direction and operating at lower temperatures from the center of the rotary plate toward the circumferential direction.

10. The single wafer etching apparatus according to claim 8, wherein the oscillator is linked with the spray nozzle and the heat supplying substrate.

11. A single wafer etching apparatus comprising:
a rotary plate having a wafer stably placed thereon and having a diameter smaller than that of the wafer;
a spray nozzle spraying an etching solution on the wafer stably placed on the rotary plate; a driver rotating the rotary plate;
a heat supplying substrate included on the rotary plate and heating each region of the rotary plate; and
a vibrator included in the heat supplying substrate and vibrating the rotary plate.

12. The single wafer etching apparatus according to claim 11, wherein the heat supplying substrate comprises a plurality of heat supplying regions divided from a center of the rotary plate in a circumferential direction and operating at lower temperatures from the center of the rotary plate toward the circumferential direction.

13. The single wafer etching apparatus according to claim 11, wherein the vibrator is linked with the spray nozzle and the heat supplying substrate.
